(19) United States
(12) Patent Application Publication
(10) Pub. No.: US 2026/0066224 A1
(43) Pub. Date: Mar. 5, 2026

(54) HYBRID PLASMA SOURCE

(71) Applicant: Tokyo Electron Limited, Tokyo (JP)

(72) Inventors: Jianping Zhao, Austin, TX (US); John Carroll, Austin, TX (US); Barton Lane, Austin, TX (US)

(21) Appl. No.: 18/824,606

(22) Filed: Sep. 4, 2024

(51) Int. Cl. H01J 37/32

(52) U.S. Cl. CPC H01J 37/321; H01J 37/32091; H01J 37/3266

(57) ABSTRACT

According to an embodiment, a hybrid plasma processing system for generating an inductively coupled plasma is proposed. The hybrid plasma processing system includes a plasma chamber, a showerhead electrode, an RF feed structure, and an inductive element. The plasma chamber includes a center electrode, showerhead, and a coaxial RF power feed. The plasma chamber is configured as a capacitively coupled plasma (CCP) chamber. The showerhead electrode is configured to control gas flow within the capacitively coupled plasma chamber. The showerhead electrode is coupled to ground. The RF feed structure is couplable to an RF source. The inductive element is coupled to the RF feed structure configured to form a resonant circuit to generate a magnetic field to sustain the inductively coupled plasma generated within the capacitively coupled plasma chamber.

### TECHNICAL FIELD

The present disclosure generally relates to plasma processing and, in particular embodiments, to a hybrid resonant capacitive-inductive plasma source.

### BACKGROUND

Two methods for generating plasma stand out in plasma processing technology: capacitive coupling and inductive coupling. Each approach offers distinct advantages and challenges, particularly in molecular dissociation and flow field control.

Capacitively generated plasma is characterized by its lower dissociation degree of molecules. This means fewer molecules are broken down into constituent atoms or smaller molecular fragments during the plasma process. While this might seem a limitation, it provides certain benefits in specific applications. One of the key advantages of capacitive coupling is the superior control it offers over the flow field. This is primarily achieved through a showerhead electrode, allowing a more uniform distribution of the plasma and its precursors across the substrate surface. The showerhead design enables precise control over gas flow and species distribution, making it possible to maintain consistency even with small gaps between the electrode and the substrate.

On the other hand, inductively generated plasma boasts a higher dissociation degree of molecules. This increased dissociation rate can be advantageous in processes that require more reactive species or aim to break down complex molecules into simpler components. Inductive coupling typically involves using a coil, which generates a magnetic field to sustain the plasma. However, this configuration presents challenges in terms of flow field control. Unlike capacitive systems, inductively coupled plasmas do not employ a showerhead electrode. They typically employ a cylindrical dielectric plate beneath the inductive antenna which can be difficult to configure as a showerhead to distribute gas. As a result, achieving uniform species distribution and maintaining consistent plasma characteristics across the substrate surface becomes more challenging. Larger gaps between the plasma source and the substrate are often necessary in inductive systems to compensate for this reduced control over the flow field.

### SUMMARY

Technical advantages are generally achieved by embodiments of this disclosure, which describe a hybrid resonant capacitive-inductive plasma source.

A first aspect relates to hybrid plasma processing system for generating an inductively coupled plasma. The hybrid plasma processing system comprising a plasma chamber comprising a center electrode, showerhead, and a coaxial RF power feed, the plasma chamber having a configuration of a capacitively coupled plasma (CCP) chamber; a showerhead electrode configured to control gas flow within the capacitively coupled plasma chamber, the showerhead electrode coupled to ground; an RF feed structure couplable to an RF source; and an inductive element coupled to the RF feed structure configured to form a resonant circuit to generate a magnetic field to sustain the inductively coupled plasma generated within the capacitively coupled plasma chamber.

A second aspect relates to a hybrid plasma processing source for generating an inductively coupled plasma. The hybrid plasma processing source comprising a showerhead electrode configured to control gas flow within a plasma chamber, the showerhead electrode coupled to ground; an RF feed structure couplable to an RF source; and an inductive element coupled to the RF feed structure configured to form a resonant circuit to generate a magnetic field to sustain the inductively coupled plasma generated within the plasma chamber.

A third aspect relates to a hybrid plasma processing source for generating an inductively coupled plasma. The hybrid plasma processing source comprising a showerhead electrode configured to control gas flow within a plasma chamber, the showerhead electrode coupled to ground and comprising a coil; an RF feed structure couplable to an RF source; and an inductive element coupled to the RF feed structure configured to form a resonant circuit to generate a magnetic field to sustain an inductively coupled plasma generated within the plasma chamber, wherein the coil is couplable to a DC or AC source, the coil configured to generate a static magnetic field or a quasi-static magnetic field to affect a property of the inductively coupled plasma.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a cross-section of a capacitively coupled plasma (CCP) processing system;

FIG. 2 is a cross-section of an inductively coupled plasma (ICP) processing system;

FIG. 3 is a cross-section of an embodiment hybrid plasma processing system;

FIG. 4 is a schematic representation of an embodiment hybrid plasma processing system; and

FIG. 5 is a cross-section of an embodiment showerhead electrode.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While inventive aspects are described primarily in the context of resonating in a plasma processing system, the inventive aspects may similarly apply to fields outside the semiconductor industry. Plasma can treat and modify surface properties through functional group addition. For example, plasma can convert hydrophobic surfaces to hydrophilic surfaces to treat surfaces for paint deposits. Further, the inventive aspects are not limited to plasma. For example, RF can be used to thaw frozen food or dry textiles, food, wood, or the like.

The fundamental differences between capacitively and inductively generated plasmas lead to distinct trade-offs in various plasma processing applications. Aspects of the disclosure propose a hybrid resonant capacitive-inductive plasma source for plasma generation. This approach combines the advantages of capacitive and inductive plasma generation methods within a single system.

Aspects of this disclosure disclose a hybrid plasma source that offers advantages by combining elements of capacitively coupled plasma (CCP) and inductively coupled plasma (ICP) systems. CCP generates plasma with a lower dissociation degree of molecules but provides better flow field control through a showerhead. This results in improved uniformity with a small gap, which is particularly beneficial for plasma-enhanced atomic layer deposition (PEALD) and plasma-enhanced atomic layer etching (PEALE). However, CCP's low dissociation degree, low plasma density, high electron energy, and high ion energy limit its applicability in certain processes, such as deep hole etching, carbon hard mask deposition, and conductor and silicon etching. In contrast, ICP generates plasma with a high degree of dissociation of molecules but offers less control over the flow field due to the absence of a showerhead. This necessitates a larger gap and chamber size for uniformity control. By combining aspects of both CCP and ICP, a hybrid plasma source can potentially overcome these limitations and enhance performance for a wider range of etch and deposition processes.

In embodiments, the disclosure proposes a plasma processing system incorporating inductive plasma generation into a capacitive coupled plasma (CCP) source configuration. This hybrid approach aims to enhance molecular dissociation, a characteristic typically associated with inductively coupled plasmas, while maintaining capacitive systems' superior flow field control. The proposed system retains a showerhead and a CCP electrode, key components for achieving precise control over the plasma distribution and gas flow. Advantageously, by merging the two plasma generation techniques, a more versatile and efficient plasma source, leveraging the strengths of both methods, is devised.

The proposed hybrid plasma generation method offers a unique combination of benefits that are not achievable with either conventional capacitively coupled plasma (CCP) or inductively coupled plasma (ICP) systems alone. The proposed approach enhances molecular dissociation while maintaining high plasma density, a feature typically associated with ICP. Simultaneously, it achieves low electron energy and a narrow ion energy distribution function (IEDF), characteristics that can be crucial for precise plasma processing. Its ability to incorporate these advantages within a standard CCP chamber configuration sets this method apart from conventional solutions. The proposed system allows for a showerhead and a narrow gap system, features that are typically challenging to implement in traditional ICP setups. By combining these elements, the proposed system creates a versatile plasma source that overcomes the limitations of both CCP and ICP systems, opening up new possibilities in plasma processing applications. These and additional details are further detailed below.

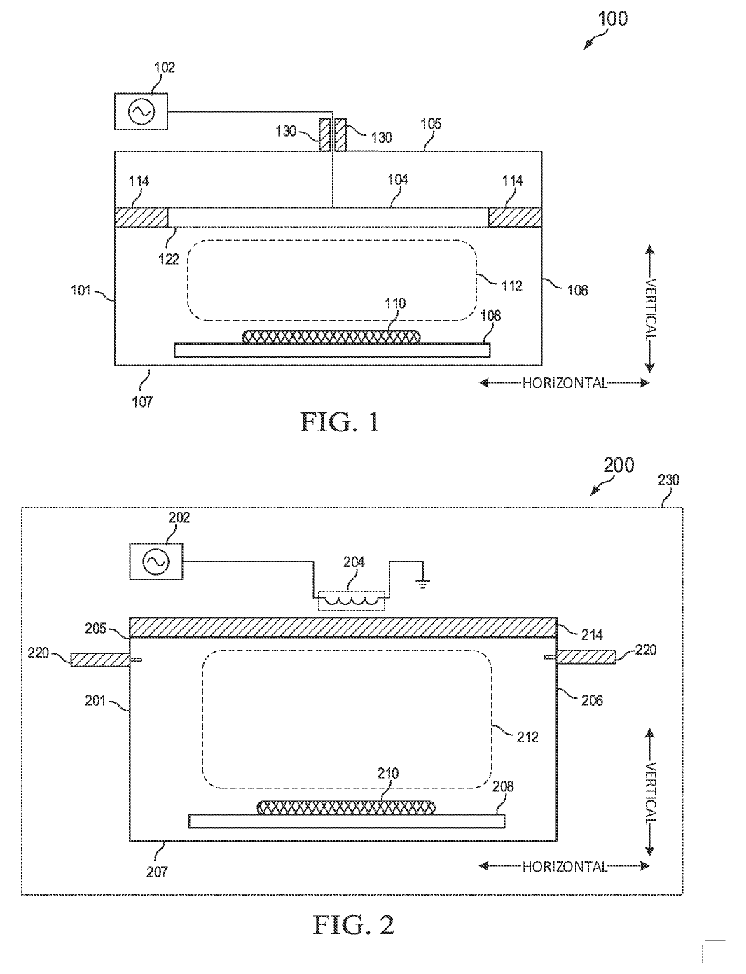

FIG. 1 illustrates a cross-section of a capacitively coupled plasma (CCP) processing system 100. CCP processing system 100 includes an RF source 102, showerhead electrode 104, a plasma chamber 106, and, optionally, a dielectric plate 114, which may (or may not) be arranged as shown in FIG. 1. Further, CCP processing system 100 may include additional components not depicted in FIG. 1, such as a matching network between the RF source 102 and the showerhead electrode 104. The CCP processing system 100 may be housed in an enclosure like a Faraday cage.

The plasma chamber 106 may include sidewalls 101, a base 107, and a top cover 105, which may be made of a conductive material, for example, stainless steel or aluminum coated with a film, such as yttria (e.g., YxOy or YxOyFz, etc.), or a film consistent with the process (e.g., carbon, silicon, etc.), or as known to a person of ordinary skill in the art. Plasma chamber 106 may be cylindrical with a base 107 and a top cover 105 that are, for example, circular or rectangular.

RF source 102 provides forward RF waves to the showerhead electrode 104 through an opening of the top cover 105. The RF feed may be isolated from the sidewalls of the opening of the top cover 105 through an insulating material 130.

The plasma chamber 106 includes the substrate holder 108 (i.e., chuck). As shown, substrate 110 is placed on substrate holder 108, positioned at the base 107 of the plasma chamber 106, to be processed. The substrate holder 108 securely holds and electrostatically clamps the substrate 110 during processing. The substrate holder 108 can be DC-biased, RF-biased, floating, or grounded. Plasma chamber 106 may include additional substrate holders (not shown). The placement of the substrate holder 108 may differ from that shown in FIG. 1.

Showerhead electrode 104 is a specialized type typically used in CCP processing systems. It serves a dual purpose, combining the functions of gas distribution and plasma generation in a single component. Showerhead electrode 104 typically consists of a flat, circular disc made of a conductive material, usually metal, with numerous small holes 122 (or perforations) distributed across its surface facing the substrate holder 108. The small holes 122, which can number hundreds or even thousands, are arranged to ensure uniform gas flow and distribution across the entire area of the showerhead electrode 104. Although in FIG. 1, the CCP processing system 100 is shown with a showerhead electrode, showerhead electrode 104 can be other types, such as parallel-plate, segmented, dual-frequency, or mesh electrodes with a separate showerhead configuration.

Showerhead electrode 104 is isolated from sidewalls 101 of the plasma chamber 106 by dielectric plate 114, typically made of a dielectric material such as quartz or alumina. Showerhead electrode 104 may be embedded within the dielectric plate 114.

Showerhead electrode 104 couples RF power from RF source 102 to the plasma chamber 106 to treat substrate 110. In particular, showerhead electrode 104 radiates an electromagnetic wave in response to being fed the forward RF waves from the RF source 102. The radiated electromagnetic wave propagates from the atmospheric side into plasma chamber 106. The radiated electromagnetic wave generates an electromagnetic field within the plasma chamber 106. The generated electromagnetic field ignites and sustains plasma 112 by transferring energy to free electrons within the plasma chamber 106. The plasma 112 can be used to, for example, selectively etch or deposit material on substrate 110.

Another function of the showerhead electrode 104 is introducing process gases into the plasma chamber 106 while simultaneously acting as one of the electrodes for plasma generation. Gases fed into the showerhead electrode 104 flow through the small holes 122 and are evenly dispersed into the plasma chamber 106. This allows for a uniform distribution of gas species across the surface of substrate 110, which can be crucial for achieving consistent plasma characteristics and processing results.

The combination of uniform gas distribution and plasma generation helps to create a homogeneous processing environment, which can be essential for many applications in semiconductor manufacturing and other industries requiring precise plasma treatments. The showerhead design allows easy control and modification of gas flow patterns, making it a versatile tool in plasma processing technology.

In CCP processing system 100, a notable advantage emerges from the showerhead configuration. The showerhead electrode 104 controls the flow field within the plasma chamber 106. Further, showerhead electrode 104 allows for the precise distribution of gases and plasma precursors across the surface of substrate 110. As a result, CCP processing system 100 can offer superior uniformity in terms of flow field control. This uniformity can benefit many plasma processing applications, ensuring consistent treatment across the substrate 110. Further, finely tuning and maintaining a uniform flow field contributes to the reliability and reproducibility of processes conducted in CCP processing system 100.

Other features of the CCP processing system 100 are low dissociation, low electron density (ne), high electron temperature (high Te), and high ion energy, which may be disadvantageous depending on the application.

For example, the degree of molecular breakdown in CCP processing system 100 is relatively low, which can pose challenges for processes requiring, for example, high dissociation levels. This limitation can become problematic in applications that demand abundant production of highly reactive species, such as fluorine or hydrogen radicals, which often necessitate deep dissociation to be effectively utilized in various plasma-based processes. As a result, CCP processing system 100 is not considered an optimal choice for applications where extensive molecular breakdown is crucial. Accordingly, the inherent characteristic of CCP processing system 100 can restrict its effectiveness in processes that rely heavily on the availability of deeply dissociated species.

As another example, the number of electrons per unit volume in the plasma 112 in the CCP processing system 100 is low. Low electron density indicates less ionization, more electronegativity, and less molecular dissociation in the plasma, which can result in lower reactivity and slower processing rates for some applications.

As another example, the average energy of electrons in the plasma 112 in the CCP processing system 100 is high. High electron temperature (i.e., and the balance between electron and ion populations) means that the electrons have high energy, which can impact plasma potential and sheath voltage, thus, increasing ion energy and affecting ion angular distribution. While this can lead to beneficial effects like increased ionization, it can also cause unwanted side effects such as large ion energy and angle distribution or undesired re-dissociation of reaction by-products in some applications.

As yet another example, the kinetic energy of the ions in the plasma 112 in the CCP processing system 100 is high. This is because the plasma is generated by creating strong electric fields in the sheaths where the plasma contacts a material surface. The electric fields accelerate ions into the material surfaces and act to heat the ions in the bulk of the plasma by increasing the space electrostatic potential in the plasma. High ion energy can benefit some processes that require energetic ion bombardment, such as certain etching applications. However, it can also lead to unwanted effects like substrate or reactor wall damage or reduced selectivity in some processes.

FIG. 2 illustrates a cross-section of an inductively coupled plasma (ICP) processing system 200. ICP processing system 200 includes an RF source 202, a radiating antenna 204, a plasma chamber 206, and, optionally, a dielectric plate 214, which may (or may not) be arranged as shown in FIG. 2. Further, ICP processing system 200 may include additional components not depicted in FIG. 2, such as a matching network between the RF source 202 and the radiating antenna 204. The ICP processing system 200 may be housed within an enclosure 230, which may be a Faraday cage or solid.

RF source 202 provides forward RF waves to the radiating antenna 204. The forward RF waves travel through the radiating antenna 204 and are transmitted (i.e., radiated) towards plasma chamber 206.

The plasma chamber 206 may include sidewalls 201, a base 207, and a top cover 205. In embodiments, the sidewalls 201 and the base 207 may be made of a conductive material, for example, stainless steel or aluminum coated with a film, such as yttria (e.g., YxOy or YxOyFz, etc.), or a film consistent with the process (e.g., carbon, silicon, etc.), or as known to a person of ordinary skill in the art. In embodiments, the top cover 205 is not conductive. In embodiments, the top cover 205 has an opening where the RF enters the plasma chamber 206. In embodiments, top cover 205 may be a hybrid conductive and non-conductive material that allows for the RF to enter the plasma chamber 206 and provide structural rigidity to the plasma chamber 206. Plasma chamber 206 may be cylindrical with a base 207 and a top cover 205 that are circular.

The plasma chamber 206 includes a substrate holder 208 (i.e., chuck). As shown, substrate 210 is placed on substrate holder 208, positioned at the base 207 of the plasma chamber 206, to be processed. The substrate holder 208 securely holds and electrostatically clamps the substrate 210 during processing. Plasma chamber 206 may include additional substrate holders (not shown). The placement of the substrate holder 208 may differ from that shown in FIG. 2. Thus, the quantity and position of the substrate holder 208 are non-limiting.

Radiating antenna 204 can be separated from the top cover 205 of the plasma chamber 206 by the dielectric plate 214 (i.e., a dielectric window), typically made of a dielectric material such as quartz. Dielectric plate 214 separates the low-pressure environment within the plasma chamber 206 from the external atmosphere. It should be appreciated that radiating antenna 204 can be placed directly adjacent to the top cover 205 of the plasma chamber 206, or radiating antenna 204 can be separated from plasma chamber 206 by air, Teflon, or ceramic. The dielectric plate 214 can be selected to minimize reflections of the RF wave from the plasma chamber 206. Radiating antenna 204 can be embedded within the dielectric plate 214.

Radiating antenna 204 couples RF power from RF source 202 to the plasma chamber 206 to treat substrate 210. In particular, radiating antenna 204 radiates an electromagnetic wave in response to being fed the forward RF waves from the RF source 202. The radiated electromagnetic wave penetrates from the atmospheric side (i.e., radiating antenna 204 side) of the dielectric plate 214 into plasma chamber 206. The radiated electromagnetic wave generates an electromagnetic field within the plasma chamber 206. The generated electromagnetic field ignites and sustains plasma 212 by transferring energy to free electrons within the plasma chamber 206. The plasma 212 can be used to, for example, selectively etch or deposit material on substrate 210.

The ICP processing system 200 may include a gas injector 220 arranged, for example, on the sidewalls 201 of the plasma chamber 206. Unlike capacitively coupled plasma systems, ICP processing system 200 typically requires a dielectric plate 214 covering the entire top of the reactor, where the radiating antenna 204 is located. The configuration presents challenges for top-down gas delivery. Incorporating a showerhead into the dielectric plate 214 can be difficult to fabricate and lead to serious issues. For example, the strong electric fields near the radiating antenna 214 can cause gas in potential showerhead channels to become ionized, resulting in problematic discharges within the dielectric plate. As a result, the gas injector 220 acts as a point source for gas delivery, introducing the process gases directly into the plasma chamber 206 from the sides.

Gas injector 220 typically consists of multiple small nozzles or ports strategically positioned around the perimeter of the plasma chamber 206, usually at regular intervals along the sidewalls 201. Each gas injector 220 is connected to a gas supply line, allowing gas flow rates and compositions to be controlled. The gas injector 220 can incorporate features to promote gas dispersion, such as angled outlets or specialized nozzle shapes, to help distribute the gases more evenly throughout the volume of the plasma chamber 206.

The ICP processing system 200 is recognized for its ability to achieve high levels of molecular dissociation. High dissociation indicates that plasma 212 effectively breaks down molecules into their constituent atoms or smaller molecular fragments. Further, high dissociation can be beneficial for processes requiring a large number of reactive species. The high disassociation characteristic of ICP processing system 200 makes it particularly advantageous for applications that require radical-driven sources or reactions. Accordingly, inductive plasma sources like the ICP processing system 200 are typically preferred when processes demand a high concentration of reactive radicals

However, achieving uniform gas distribution across the entire substrate surface can be more challenging with the sidewall locations of gas injector 220 in ICP processing system 200 than with showerhead designs. The arrangement of components in the ICP processing system 200 can restrict gas delivery options, forcing the gas injector 220 as the primary method of introducing gases into the chamber. The gas injectors are usually positioned around the sidewalls of the chamber, creating a gas delivery system that is inherently less uniform than the showerhead design found in CCP processing system 100. This limitation in gas distribution can pose challenges for achieving uniform plasma characteristics across the entire substrate surface in ICP processing system 200.

Specifically, a concern arises when operating at high pressures in the presence of radio frequency fields. Under these conditions, the RF field (i.e., "R field") can induce non-uniform charge distributions within the plasma 212. This phenomenon occurs due to the interactions between the RF energy and the more densely packed gas molecules at higher pressures, such as near or in the gas injectors. As the pressure increases, the mean free path of charged particles decreases, leading to more frequent collisions. Combined with strong RF fields, this can result in localized areas of varying charge density throughout the plasma volume. These non-uniform charge distributions may manifest as regions of higher or lower density than the surrounding plasma 212, potentially causing issues such as enhanced localized ionization, charge trapping in RF-induced potential wells, or forming standing waves. The localized higher-density discharge near or in the gas injectors is often unstable, causing plasma instability and can damage the gas injectors. Such non-uniformities can significantly impact the plasma processing quality, leading to inconsistent ion bombardment energies, potential arcing, and overall reduced control over the plasma characteristics. Further, the non-uniformities can adversely affect IC yield across the processed substrate. In severe cases, they may lead to catastrophic events such as arcing or localized gas injector plasma ignition, commonly called “light-up.” These phenomena compromise process uniformity and threaten equipment integrity and overall manufacturing efficiency.

Further, using inductive coils and gas injectors in the ICP processing system 200 necessitates a wider gap between the plasma source and the substrate 110. Moreover, the need to accommodate the inductive coils and ensure proper plasma formation results in the ICP processing system 200 requiring a larger diameter chamber than the CCP processing system 100. A large gap and a wide chamber diameter can affect process efficiency. When considering the gas dynamics in such a system, it can become apparent that filling the plasma chamber 206 with process gases using the gas injector 220 and subsequently pumping them out can be a relatively slow process. This is due to the larger volume that needs to be filled and evacuated in each processing cycle. The time required for gas exchange in these larger chambers can impact overall process throughput and efficiency, especially in applications requiring rapid gas switching or pressure changes, such as atomic layer deposition or etching or cyclic plasma process.

For example, CCP chambers typically have a diameter ranging from 300 to 500 millimeters. In contrast, ICP chambers are generally larger than CCP chambers to facilitate better gas mixing, although specific dimensions are not widely standardized. The gap distance, the space between the powered electrode and the substrate or grounded electrode, also differs between these two chamber types. CCP systems usually operate with a 10 to 30 millimeters gap, while ICP systems commonly employ a much larger gap of around 100 millimeters. The dimensional differences reflect the distinct operational characteristics and requirements of CCP and ICP systems in plasma processing applications.

Other features of the ICP processing system 200 are high electron density (ne), low electron temperature (low Te), and low ion energy. For example, the number of electrons per unit volume in the plasma 212 in the ICP processing system 200 is high. High electron density indicates more ionization and electro-positivity in the plasma 212, leading to increased reactivity and faster processing rates.

As another example, the average energy of electrons in the plasma 212 in the ICP processing system 200 is low. Low electron temperature means that the electrons have low energy. Low electron temperature (and the balance between electron and ion populations) impact plasma potential and sheath voltage; thus, decreasing ion energy and less affecting ion angular distribution. Low electron energy can benefit processes requiring low damage, better ion energy and angle distribution control or high selectivity.

As yet another example, the kinetic energy of the ions in the plasma 212 in the ICP processing system 200 is low. Low ion energy can benefit some processes that require less energetic ion bombardment, such as certain etching applications requiring precise or smooth etching.

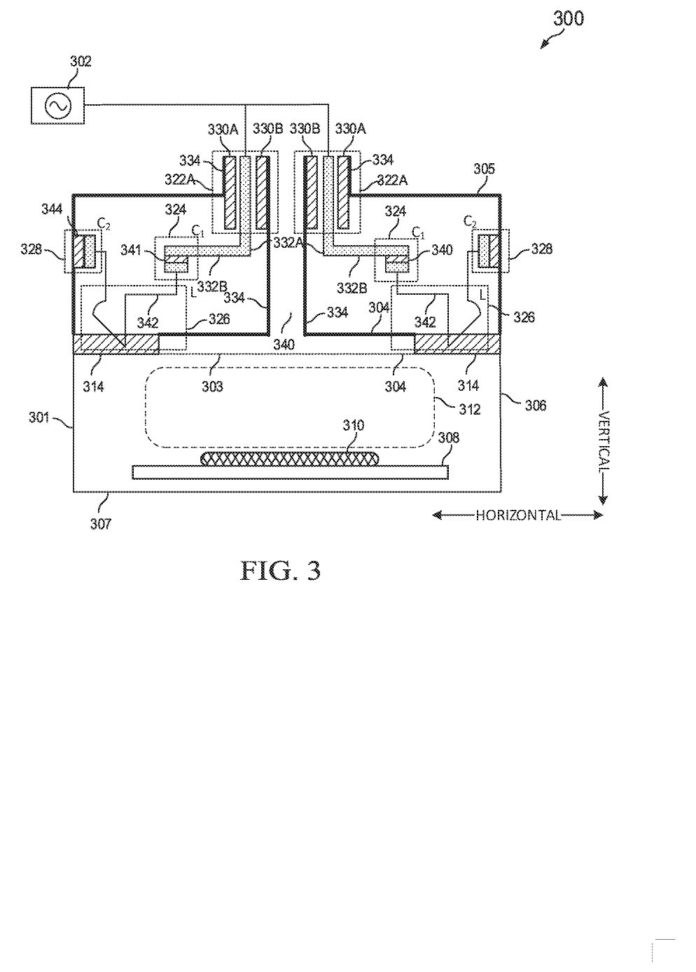

FIG. 3 illustrates a cross-section of an embodiment hybrid plasma processing system 300. The system is configured to have a hybrid resonant capacitive-inductive plasma source. Hybrid plasma processing system 300 includes an RF source 302, showerhead electrode 304, a plasma chamber 306, an RF feed structure 322, a dielectric plate 314, a first capacitive element (C₁) 324, an inductive element (L) 326, and a second capacitive element (C₂) 328, which may (or may not) be arranged as shown. Further, hybrid plasma processing system 300 may include additional components not depicted, such as a matching network between the RF source 302 and the RF feed structure 322. The hybrid plasma processing system 300 may be housed in an enclosure like a Faraday cage.

In hybrid plasma processing system 300, an objective is to achieve better control over ion energy, specifically aiming for a narrow ion energy distribution. This approach addresses a limitation found in conventional CCP processing systems. In the CCP processing system 100, the potential of the showerhead electrode 104 oscillates, resulting in a broad distribution of ion energies.

Hybrid plasma processing system 300 introduces a solution to this challenge by grounding the showerhead electrode 304. By maintaining the potential of the showerhead electrode 304 at zero potential, hybrid plasma processing system 300 eliminates RF oscillations caused by the showerhead electrode 104.

In embodiments, the showerhead electrode 304 is coupled to ground, DC ground, or RF ground. In embodiments, the showerhead electrode 304 is coupled to a set DC potential, which may encompass a range of DC potentials that has a time scale that is much longer than the RF time scale. For example, the set DC potential may be 0 V or 5 V. In embodiments, the showerhead electrode 304 is coupled to a continuous wave potential of zero. Specifically, in contrast to the CCP processing system 100, where the RF source 102 is coupled to the showerhead electrode 104, in the hybrid plasma processing system 300, the RF source 302 is not coupled to the showerhead electrode 304.

Through the small holes 303, showerhead electrode 304 introduces gases into the plasma chamber 306. Gases fed from the inlet 340 into the showerhead electrode 304 flow through the small holes 303 and are evenly dispersed into the plasma chamber 306. This allows for a uniform distribution of gas species across the surface of substrate 310.

The grounding of the showerhead electrode 304 leads to a more narrowly controlled ion energy distribution, even when operating at the same frequency as conventional CCP processing systems. The ability to achieve tighter control over ion energies represents a significant advantage of the hybrid plasma processing system 300. It offers the potential for more precise plasma processing, as the narrow ion energy distribution can lead to improved uniformity and control in various applications, such as etching or thin film deposition. Accordingly, this feature of hybrid plasma processing system 300 demonstrates its capacity to overcome some of the inherent limitations of traditional CCP processing system configurations while maintaining the benefits of a showerhead design for uniform gas distribution.

The coupling of RF power from the RF source 302 to a resonance structure can be realized through an RF feed structure 322. In embodiments, the RF feed structure 322 is a double coaxial RF structure that includes a grounded metal 334 with a dielectric 330 positioned between each RF line 332 and the grounded metal 334. The RF power flows through the RF line 332, passing through a first capacitive element (C₁) 324 before coupling to an inductive element (L) 326. The current can continue its path through a second capacitive element (C₂) 328 to ground through the sidewall 301. The first capacitive element (C₁) 324, the inductive element (L) 326, and the second capacitive element (C₂) 328 form a CLC (Capacitor-Inductor-Capacitor) resonance structure.

The inductance and capacitance values of the CLC resonance structure determine the resonant frequency of the hybrid plasma processing system 300. Accordingly, by adjusting these values, hybrid plasma processing system 300 can operate at different frequencies based on the specific requirements of the plasma process.

In embodiments, the dielectric 330 is air, Teflon, quartz, or ceramic. Dielectric 330 may be a cylindrical structure arranged symmetrically to a central vertical axis of the hybrid plasma processing system 300. Dielectric 330 can include a first ring portion 330A and a second ring portion 330B. The first ring portion 330A is positioned adjacent to the outer wall portion of the grounded metal 334, while the second ring portion 330B is positioned adjacent to the inner wall portion of the grounded metal 334, closer to the central vertical axis. The second ring portion 330B surrounds and insulates the RF line 332.

The RF feed structure 322 may include a cylindrical conductive material and multiple conductive vertical structures arranged between the first ring portion 330A and the second ring portion 330B.

The RF feed structure 322 can have multiple configurations, depending on the specific design requirements. In an embodiment, the RF-carrying element may consist of several disjoint arcs of a cylinder, symmetrically arranged around the central vertical axis of the system rather than a complete cylinder. Alternatively, multiple complete feed structures could be arranged non-concentrically around the central axis, each with its own set of nested elements. These configurations create multiple insulated channels within the overall RF feed structure 322, controlling and directing the RF power flow. The dielectric 330 serves as an insulating barrier between the grounded elements and the RF-carrying elements, regardless of their specific geometry.

In some embodiments, the dielectric 330 forms ring structures in openings at the top cover 305 of the plasma chamber 306. These openings (e.g., via structures) can be positioned at equidistance (but not required) from the central vertical axis of the hybrid plasma processing system 300. Each ring structure consists of the first ring portion 330A and the second ring portion 330B, with an RF line 332 positioned vertically within, isolated from the grounded metal 334 by the dielectric 330.

The RF feed structure (i.e., RF line 332) can include three main components: an inner ground element, an outer ground element, and a central RF-carrying element. In a horizontal cross-section, these elements can take various shapes, as long as the inner ground element is contained within the RF-carrying element, which in turn is contained within the outer ground element. While cylindrical shapes are common, other geometries, such as hexagons or complex shapes, are possible. The RF-carrying element need not be a single continuous structure; it could include multiple disjoint vertical structures, such as a collection of vertical tubes 332A positioned at various distances from the central axis of symmetry, all contained between the inner and grounded elements. The vertical portion 332A of the elements are electrically coupled to the respective horizontal portion 332Band may be mechanically coupled at multiple locations to ensure structural integrity and consistent electrical performance.

In embodiments, the first capacitive element (C₁) 324 is formed by two conductive parts separated by an insulator, ensuring no DC connection. One conductive path can be coupled to the power source via the feed structure (i.e., RF line 332), while the other can be coupled to the inductive structure. The geometry of the capacitive structure can be complex, according to various designs and spatial constraints. The insulator between the conductive parts (i.e., dielectric 341) can be air, Teflon, quartz, ceramic, or any suitable dielectric material. In embodiments, dielectric 341 is a cylindrical structure or other shapes.

The second RF line 342 is a conductive structure that forms the inductive element (L) 326, which is proximate to the plasma 312. The current flowing through the inductive element (L) 326 generates a magnetic field, which passes through the dielectric plate 314 into the plasma chamber 306. The second RF line 342 can take various forms, such as a rod, plate, hollow structure, or tubing.

In embodiments, the second capacitive element (C₂) 328 is formed by the grounded outer portion of the plasma chamber 306, a dielectric 344, and a second portion of the second RF line 342. In embodiments, dielectric 344 is air, Teflon, quartz, or ceramic. In embodiments, the grounded outer portion of the plasma chamber 306 is the sidewall 301 of the plasma chamber 306 (as shown) or the top cover 305 of the plasma chamber 306. In embodiments, the second portion of the second RF line 342 is floating (i.e., not coupled through the second capacitive element (C₂) 328 to ground). In embodiments, the second portion of the second RF line 342 is grounded.

In embodiments, dielectric plate 314 is a dielectric ring surrounding the showerhead electrode 304. In embodiments, dielectric plate 314 is air, Teflon, quartz, or ceramic. In embodiments, the inductive element (L) 326 of the CLC resonance structure is arranged within, adjacent to, or above the dielectric plate 314. The inductive element (L) 326 is capacitively coupled through the first capacitive element (C₁) 324 to the RF source 302 via the RF feed structure 322. In embodiments, the inductive element (L) 326 is capacitively coupled through the second capacitive element (C₂) 328 to ground. In embodiments, the magnetic field generated by the CLC (or LC) resonance circuit is coupled into plasma 312 through the dielectric plate 314.

In embodiments, the magnetic field induces counter current to the current carried by the CLC (or LC) resonant circuit. This results in electrons being heated by the parallel (i.e., horizontal) polarized electric field and current (azimuthally on a normal reactor configuration).

In embodiments, the showerhead electrode 304 is centrally positioned along the center axis of the plasma chamber 306. In embodiments, the showerhead electrode 304 is grounded through, for example, the body of the plasma chamber 306. In embodiments, showerhead electrode 304 is DC or RF biased, as further disclosed in FIG. 5. In embodiments, the biasing may be continuous or pulsed. In embodiments, a circuit, such as a large series capacitor, couples the showerhead electrode 304 to the outer wall of the plasma chamber 306.

Showerhead electrode 304 enables gas delivery through the inlet 340 and the small holes 303. In embodiments, showerhead electrode 304 enables remote plasma source attachment. In embodiments, showerhead electrode 304 enables other plasma control or sensing accessories, such as sensors coupled to the showerhead electrode 304. In embodiments, showerhead electrode enables embedded permanent magnets or electromagnetic coils.

In embodiments, the first capacitive element (C₁) 324 has a capacitance value between 1 picofarad (pF) and 1000 nanofarad (nF). In an embodiment, the capacitance of the first capacitive element (C₁) 324 is 185 pF.

In embodiments, the second capacitive element (C₂) 328 has a capacitance value between 1 pF and 1000 nF. In an embodiment, the capacitance of the second capacitive element (C₂) 328 is 95 pF.

In embodiments, the inductive element has an inductance value between 1 picohenry (pH) and 1000 nanohenry (nH). In an embodiment, the inductance of the inductive element is 75 nH.

A dielectric plate 314 isolates the resonant structure and the showerhead from ground.

In hybrid plasma processing system 300, plasma 312 is primarily powered by an inductive field, which generates the radicals necessary for various plasma processes. Simultaneously, the system incorporates a showerhead, which provides precise control over the flow field within the plasma chamber 306.

Combining ICP and CCP features in the hybrid plasma processing system 300 offers significant advantages, particularly for deposition processes. Hybrid plasma processing system 300 addresses a common issue in traditional ICP processing systems that rely solely on gas injectors, where gas delivery often lacks uniformity. Such systems typically require operation at low pressures to compensate for non-uniform gas distribution. In contrast, the proposed hybrid approach allows for more efficient operation at higher pressures, such as hundreds of milliTorr to several Torr ranges, which is generally not feasible with standard gas injection methods. The integration of inductive power for radical generation and a showerhead for uniform gas distribution represents an improvement in plasma processing technology, especially for applications demanding precise control over deposition parameters and uniformity.

Hybrid plasma processing system 300 offers unique advantages that address limitations in traditional capacitively coupled plasma and inductively coupled plasma processing systems, such as the CCP processing system 100 and the ICP processing system 200. Hybrid plasma processing system 300 enhances molecular dissociation while maintaining high plasma density, a feature typically associated with the ICP processing system 200.

Simultaneously, hybrid plasma processing system 300 achieves low electron energy and a narrow ion energy distribution function (IEDF), characteristics that can be crucial for precise plasma processing. Its ability to incorporate these benefits within a standard plasma chamber configuration sets the hybrid plasma processing system 300 apart from the CCP processing system 100 and ICP processing system 200. Hybrid plasma processing system 300 allows for a showerhead and a narrow gap system, features that are typically challenging to implement in the ICP processing system 200.

Combining these elements, the hybrid plasma processing system 300 creates a versatile plasma source that overcomes the limitations of the CCP processing system 100 and the ICP processing system 200, opening up new possibilities in plasma processing applications. The proposed hybrid approach represents a significant advancement in plasma technology, offering a previously unattainable solution with either the CCP processing system 100 or the ICP processing system 200 alone.

Hybrid plasma processing system 300 incorporates an inductive plasma based on a resonator circuit, which differs from traditional inductively coupled plasma (ICP) designs. The proposed approach offers several advantages, including high plasma density that increases deposition and etch rates. Hybrid plasma processing system 300 can potentially achieve a Druyvesteyn electron energy distribution function (EEDF), resulting in a high degree of dissociation. Additionally, hybrid plasma processing system 300 minimizes capacitive coupling, which allows for a narrower ion energy distribution function (IEDF) and improved ion energy control.

Another feature of the hybrid plasma processing system 300 is the grounded showerhead electrode 304, which eliminates oscillating self-DC bias and ensures that ion energy is fully defined by the pulsing DC bias. The grounding of the showerhead electrode 304 allows for the incorporation of a shower head or remote radical source and another sensor or magnetic field generation device on top of the chamber or embedded in the showerhead.

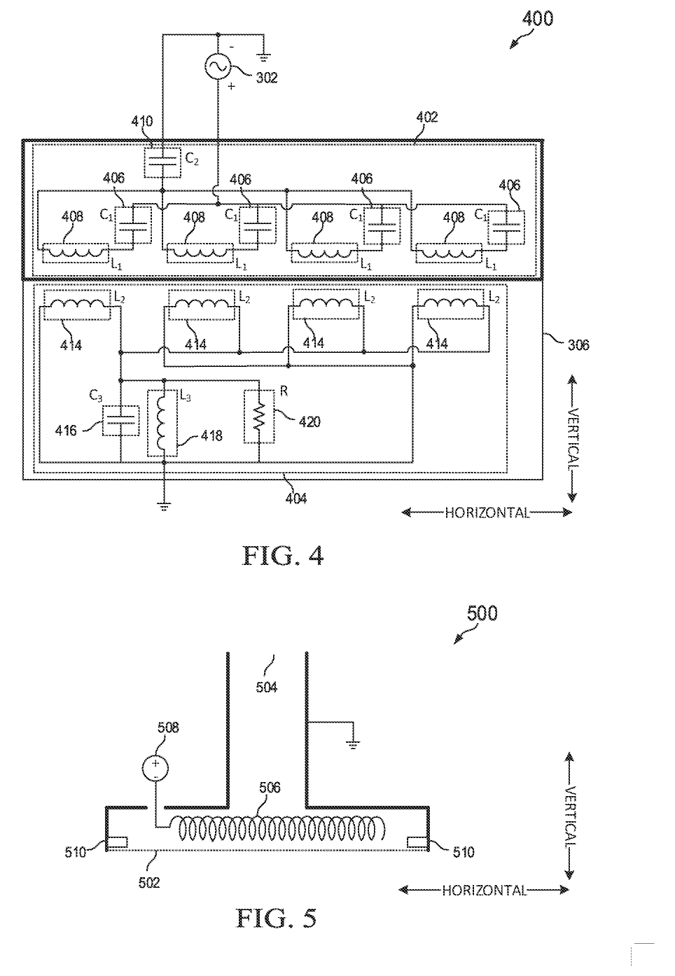

FIG. 4 illustrates a schematic representation of an embodiment hybrid plasma processing system 400, which may be implemented in the hybrid plasma processing system 300. As shown, the hybrid plasma processing system 400 can be represented as two circuits: a source circuit 402 and a plasma circuit 404, which may (or may not) be arranged as shown.

The source circuit 402 is represented using first capacitors (C₁) 406, first inductors (L₁) 408, and second capacitor (C₂) 410, which is coupled to the RF source 302. In embodiments, the first capacitive element (C₁) 324 of hybrid plasma processing system 300 is represented as the first capacitors (C₁) 406. In embodiments, the inductive element (L) 326 is represented as one of the first inductors (L₁) 408. In embodiments, the second capacitive element (C₂) 328 is represented as the second capacitor (C₂) 410.

The source circuit 402 shows four sets of first inductors (L₁) 408 and first capacitors (C₁) 406. This differs from FIG. 3, which illustrates two of the inductive element (L) 326 and two of the first capacitive element (C₁) 324. The difference arises because FIG. 3 depicts a cross-section of the hybrid plasma processing system 300 with a CLC resonance circuit containing an even number of these components. It's important to note that while four sets are shown in the source circuit 402, this number is not fixed. Embodiments with more or fewer sets of these components are also possible.

Similarly, although a single second capacitor (C₂) 410 is shown in source circuit 402 to illustrate, for example, a conductive ring parallel to the top cover 305 and separated by a dielectric, embodiments with more or fewer sets of these components are also possible and the illustrated quantity of the second capacitor (C₂) 410 is non-limiting, can be collectively or individually coupled to each first capacitors (C₁) 406 and first inductors (L₁) 408.

A CLC resonance circuit is formed by the first capacitors (C₁) 406, first inductors (L₁) 408, and the second capacitor (C₂) 410. The CLC resonance circuit generates a magnetic field coupled to plasma circuit 404.

The plasma circuit 404 is represented using second inductors (L₂) 414, a third capacitor (C₃) 416, a third inductor (L₃) 418, and a resistor (R) 420, which may (or may not be arranged as shown). The circuit model represents the inductive plasma in a simplified form. In this model, the second inductors (L₂) 414 do not represent a physical inductor but rather the inductance created by the counter current induced by the current flow in the first inductors (L₁) 408. The induced current is a characteristic of inductive coupling in plasma systems. The third capacitor (C₃) 416, the third inductor (L₃) 418, and the resistor (R) 420 collectively represent a simplified model of the plasma. The components capture the basic electrical properties of the plasma, including its capacitive, inductive, and resistive aspects.

Accordingly, embodiments of this disclosure propose a plasma generating source that combines the advantages of capacitively coupled plasma and inductively coupled plasma systems while overcoming their limitations. It enhances molecular dissociation and achieves high plasma density, low electron energy, and a narrow ion energy distribution function (IEDF). Simultaneously, it can maintain a regular CCP-type chamber configuration, allowing for the incorporation of a showerhead and a narrow gap system. This combination of features is not attainable with either CCP or ICP plasma sources alone. The hybrid design enables improved process control and efficiency, making it suitable for advanced semiconductor manufacturing processes requiring precise plasma characteristics and uniformity control.

A hybrid plasma source is proposed to address the limitations in conventional plasma processing systems, combining inductive plasma generation with a capacitively coupled plasm system configuration. In embodiments, the proposed hybrid system incorporates a resonant circuit atop an edge dielectric insulator, capacitively coupled to the RF coaxial feed and ground. The RF current in the resonant circuit generates a magnetic field that couples into the plasma through the edge dielectric insulator, inducing a counter current. The proposed configuration allows for electron heating by the parallel polarized electric field and current, typically azimuthal in standard reactor configurations.

The hybrid source can achieve high plasma density, high dissociation degree, and high deposition and etch rates through inductive plasma heating while minimizing CCP coupling. This results in a narrower ion energy distribution function (IEDF) and improved ion energy control. The proposed system also features a grounded center CCP-type electrode, eliminating oscillating self-DC bias to enhance ion energy control further. Additionally, the configuration accommodates a remote radical source for chamber cleaning and other control mechanisms such as magnet disks or electromagnetic coils. It also allows for integrating light sources or sensors into the electrode, offering increased flexibility and process control capabilities.

FIG. 5 illustrates a cross-section of an embodiment showerhead electrode 500, which may be implemented as the showerhead electrode 304 of the hybrid plasma processing system 300. Showerhead electrode 500 can be a structural housing for a control mechanism and the traditional gas distribution component. The control mechanism can integrate plasma control capabilities into existing system architecture.

Showerhead electrode 500 includes an inlet 504 for gas to flow through the small openings 502 towards the plasma. The body of the showerhead electrode 500 is coupled to ground, which may be DC ground or RF ground.

The grounding of the showerhead electrode 500 allows for the placement of sensors 510 to sense or control various plasma parameters. In embodiments, sensor 510 is an optical sensor used for detecting thickness (e.g., using an interferometer), detecting plasma species (e.g., using optical emission spectroscopy (OES)), measuring stress, measuring surface bonding characteristics (e.g., using infrared spectroscopy), or the like).

In embodiments, a coil 506 is embedded within the showerhead electrode 500. The coil 506 can include multiple turns of wire designed to carry current and generate a magnetic field. The coil 506 can be coupled to a DC or AC source 508. Unlike the primary plasma generation mechanism, the purpose of the coil 506 is to allow fine-tuning of plasma characteristics, such as uniformity, through the application of a magnetic field. In embodiments. the coil 506 carries a low-frequency current, producing a static or quasi-static magnetic field. The magnetic field can be manipulated by varying the current flow, such as pulsing it on and off at intervals much longer than the typical RF timescale by, for example, alternating between one second on and one second off. The slow variation ensures that the magnetic field can effectively penetrate the showerhead, which acts as a Faraday cage for rapidly charging fields, and influence the plasma properties.

In embodiments, by adjusting the quasi-static magnetic field through, for example, the DC source 508, operators can influence the plasma's behavior, potentially pushing it towards or away from the center of the processing chamber. The flexibility provided by coil 506 offers the flexibility to enhance uniformity or modify the distribution of radical species within the plasma.

A first aspect relates to hybrid plasma processing system for generating an inductively coupled plasma. The hybrid plasma processing system comprising a plasma chamber comprising a center electrode, showerhead, and a coaxial RF power feed, the plasma chamber having a configuration of a capacitively coupled plasma (CCP) chamber; a showerhead electrode configured to control gas flow within the capacitively coupled plasma chamber, the showerhead electrode coupled to ground; an RF feed structure couplable to an RF source; and an inductive element coupled to the RF feed structure configured to form a resonant circuit to generate a magnetic field to sustain the inductively coupled plasma generated within the capacitively coupled plasma chamber.

In a first implementation of the hybrid plasma processing system, according to the first aspect as such, the resonant circuit comprises a capacitive element formed between the RF feed structure and a first portion of the inductive element.

In a second implementation of the hybrid plasma processing system, according to the first aspect as such or any preceding implementation of the first aspect, the capacitive element further comprises a dielectric between the RF feed structure and the first portion of the inductive element.

In a third implementation of the hybrid plasma processing system, according to the first aspect as such or any preceding implementation of the first aspect, the resonant circuit comprises a second capacitive element formed between a second portion of the inductive element and a top cover or a sidewall of the plasma chamber.

In a fourth implementation of the hybrid plasma processing system, according to the first aspect as such or any preceding implementation of the first aspect, the second capacitive element further comprises a dielectric between the second portion of the inductive element and the top cover or the sidewall of the plasma chamber.

In a fifth implementation of the hybrid plasma processing system, according to the first aspect as such or any preceding implementation of the first aspect, the RF feed structure comprises a double coaxial RF structure.

In a sixth implementation of the hybrid plasma processing system, according to the first aspect as such or any preceding implementation of the first aspect, the showerhead electrode includes a sensor for sensing the inductively coupled plasma, a wafer surface, or a combination thereof.

A second aspect relates to a hybrid plasma processing source for generating an inductively coupled plasma. The hybrid plasma processing source comprising a showerhead electrode configured to control gas flow within a plasma chamber, the showerhead electrode coupled to ground; an RF feed structure couplable to an RF source; and an inductive element coupled to the RF feed structure configured to form a resonant circuit to generate a magnetic field to sustain the inductively coupled plasma generated within the plasma chamber.

In a first implementation of the hybrid plasma processing source, according to the second aspect as such, the resonant circuit comprises a capacitive element formed between the RF feed structure and a first portion of the inductive element.

In a second implementation of the hybrid plasma processing source, according to the second aspect as such or any preceding implementation of the second aspect, the capacitive element further comprises a dielectric between the RF feed structure and the first portion of the inductive element.

In a third implementation of the hybrid plasma processing source, according to the second aspect as such or any preceding implementation of the second aspect, the resonant circuit comprises a second capacitive element formed between a second portion of the inductive element and a top cover or a sidewall of the plasma chamber.

In a fourth implementation of the hybrid plasma processing source, according to the second aspect as such or any preceding implementation of the second aspect, the second capacitive element further comprises a dielectric between the second portion of the inductive element and the top cover or the sidewall of the plasma chamber.

In a fifth implementation of the hybrid plasma processing source, according to the second aspect as such or any preceding implementation of the second aspect, the RF feed structure comprises a double coaxial RF structure.

In a sixth implementation of the hybrid plasma processing source, according to the second aspect as such or any preceding implementation of the second aspect, the showerhead electrode includes a sensor for sensing the inductively coupled plasma, a wafer surface, or a combination thereof.

A third aspect relates to a hybrid plasma processing source for generating an inductively coupled plasma. The hybrid plasma processing source comprising a showerhead electrode configured to control gas flow within a plasma chamber, the showerhead electrode coupled to ground and comprising a coil; an RF feed structure couplable to an RF source; and an inductive element coupled to the RF feed structure configured to form a resonant circuit to generate a magnetic field to sustain an inductively coupled plasma generated within the plasma chamber, wherein the coil is couplable to a DC or AC source, the coil configured to generate a static magnetic field or a quasi-static magnetic field to affect a property of the inductively coupled plasma.

In a first implementation of the hybrid plasma processing source, according to the third aspect as such, the coil is configured to carry a low-frequency current to produce the static magnetic field or the quasi-static magnetic field.

In a second implementation of the hybrid plasma processing source, according to the third aspect as such or any preceding implementation of the third aspect, the static magnetic field or quasi-static magnetic field is manipulated by varying the low-frequency current.

In a third implementation of the hybrid plasma processing source, according to the third aspect as such or any preceding implementation of the third aspect, the static magnetic field or quasi-static magnetic field is manipulated by alternatively pulsing the low-frequency current on and off at pre-determined intervals.

In a fourth implementation of the hybrid plasma processing source, according to the third aspect as such or any preceding implementation of the third aspect, the showerhead electrode includes a sensor for sensing the inductively coupled plasma, a wafer surface, or a combination thereof.

In a fifth implementation of the hybrid plasma processing source, according to the third aspect as such or any preceding implementation of the third aspect, the resonant circuit comprises: a first capacitive element formed between the RF feed structure, a first portion of the inductive element, and a first dielectric between the RF feed structure and the first portion of the inductive element; and a second capacitive element formed between a second portion of the inductive element, a top cover or a sidewall of the plasma chamber, and a second dielectric between the second portion of the inductive element and the top cover or the sidewall of the plasma chamber.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. A hybrid plasma processing system for generating an inductively coupled plasma, the hybrid plasma processing system comprising:
a plasma chamber comprising a center electrode, showerhead, and a coaxial RF power feed, the plasma chamber having a configuration of a capacitively coupled plasma (CCP) chamber;
a showerhead electrode configured to control gas flow within the capacitively coupled plasma chamber, the showerhead electrode coupled to ground;
an RF feed structure couplable to an RF source; and
an inductive element coupled to the RF feed structure configured to form a resonant circuit to generate a magnetic field to sustain the inductively coupled plasma generated within the capacitively coupled plasma chamber.

2. The hybrid plasma processing system of claim 1, wherein the resonant circuit comprises a capacitive element formed between the RF feed structure and a first portion of the inductive element.

3. The hybrid plasma processing system of claim 2, wherein the capacitive element further comprises a dielectric between the RF feed structure and the first portion of the inductive element.

4. The hybrid plasma processing system of claim 2, wherein the resonant circuit comprises a second capacitive element formed between a second portion of the inductive element and a top cover or a sidewall of the plasma chamber.

5. The hybrid plasma processing system of claim 4, wherein the second capacitive element further comprises a dielectric between the second portion of the inductive element and the top cover or the sidewall of the plasma chamber.

6. The hybrid plasma processing system of claim 1, wherein the RF feed structure comprises a double coaxial RF structure.

7. The hybrid plasma processing system of claim 1, wherein the showerhead electrode includes a sensor for sensing the inductively coupled plasma, a wafer surface, or a combination thereof.

8. A hybrid plasma processing source for generating an inductively coupled plasma, the hybrid plasma processing source comprising:
a showerhead electrode configured to control gas flow within a plasma chamber, the showerhead electrode coupled to ground;
an RF feed structure couplable to an RF source; and
an inductive element coupled to the RF feed structure configured to form a resonant circuit to generate a magnetic field to sustain the inductively coupled plasma generated within the plasma chamber.

9. The hybrid plasma processing source of claim 8, wherein the resonant circuit comprises a capacitive element formed between the RF feed structure and a first portion of the inductive element.

10. The hybrid plasma processing source of claim 9, wherein the capacitive element further comprises a dielectric between the RF feed structure and the first portion of the inductive element.

11. The hybrid plasma processing source of claim 9, wherein the resonant circuit comprises a second capacitive element formed between a second portion of the inductive element and a top cover or a sidewall of the plasma chamber.

12. The hybrid plasma processing source of claim 11, wherein the second capacitive element further comprises a dielectric between the second portion of the inductive element and the top cover or the sidewall of the plasma chamber.

13. The hybrid plasma processing source of claim 8, wherein the RF feed structure comprises a double coaxial RF structure.

14. The hybrid plasma processing source of claim 8, wherein the showerhead electrode includes a sensor for sensing the inductively coupled plasma, a wafer surface, or a combination thereof.

15. A hybrid plasma processing source for generating an inductively coupled plasma, the hybrid plasma processing source comprising:
a showerhead electrode configured to control gas flow within a plasma chamber, the showerhead electrode coupled to ground and comprising a coil;
an RF feed structure couplable to an RF source; and
an inductive element coupled to the RF feed structure configured to form a resonant circuit to generate a magnetic field to sustain an inductively coupled plasma generated within the plasma chamber,
wherein the coil is couplable to a DC or AC source, the coil configured to generate a static magnetic field or a quasi-static magnetic field to affect a property of the inductively coupled plasma.

16. The hybrid plasma processing source of claim 15, wherein the coil is configured to carry a low-frequency current to produce the static magnetic field or the quasi-static magnetic field.

17. The hybrid plasma processing source of claim 15, wherein the static magnetic field or quasi-static magnetic field is manipulated by varying the low-frequency current.

18. The hybrid plasma processing source of claim 15, wherein the static magnetic field or quasi-static magnetic field is manipulated by alternatively pulsing the low-frequency current on and off at pre-determined intervals.

19. The hybrid plasma processing source of claim 15, wherein the showerhead electrode includes a sensor for sensing the inductively coupled plasma, a wafer surface, or a combination thereof.

20. The hybrid plasma processing source of claim 15, wherein the resonant circuit comprises:
a first capacitive element formed between the RF feed structure, a first portion of the inductive element, and a first dielectric between the RF feed structure and the first portion of the inductive element; and
a second capacitive element formed between a second portion of the inductive element, a top cover or a sidewall of the plasma chamber, and a second dielectric between the second portion of the inductive element and the top cover or the sidewall of the plasma chamber.
